(19) United States
(12) Patent Application Publication
(10) Pub. No.: US 2025/0285872 A1
(43) Pub. Date: Sep. 11, 2025

(54) PROCESSING METHOD

(71) Applicant: DISCO CORPORATION, Tokyo (JP)

(72) Inventors: Nobuyasu Kitahara, Tokyo (JP); Zhiwen Chen, Tokyo (JP); Shunsuke Teranishi, Tokyo (JP); Atsushi Oda, Tokyo (JP)

(21) Appl. No.: 19/061,107

(22) Filed: Feb. 24, 2025

(30) Foreign Application Priority Data
Mar. 5, 2024 (JP) 2024033032

(51) Int. Cl. H01L 21/304; B24B 7/22; H01L 21/683

(52) U.S. Cl. CPC H01L 21/304; B24B 7/228; H01L 21/6835

(57) ABSTRACT

A processing method includes forming a recess circumferentially along a support plate including a face having a size equal to or larger than the diameter of a device region and supporting a device wafer, in an outer circumferential region of the face that is positioned outwardly of a central region thereof that is commensurate with the device region, affixing the face of the support plate and the face side of the device wafer to each other with use of at least resin supplied to the recess, thinning down the device wafer by grinding or polishing or by grinding and polishing a reverse side of the device wafer, removing a region of the resin circumferentially along the device wafer, thereby to reduce a bonding force between the device wafer and the support plate, and separating a portion of the device wafer that includes the device region from the support plate.

### BACKGROUND OF THE INVENTION

### Field of the Invention

The present invention relates to a processing method of processing a device wafer having on its face side a device region where devices have been formed and an excess outer circumferential region surrounding the device region.

### Description of the Related Art

Electronic appliances such as cellular phones and personal computers (PCs) incorporate device chips. Device chips are manufactured as follows, for example. A wafer of monocrystalline silicon that has a plurality of devices such as integrated circuits (ICs) constructed on its face side is thinned down by having its reverse side ground by a grinding apparatus. Then, the thinned wafer is divided by a cutting apparatus into device chips including the respective devices.

In recent years, there have been demands in the art for wafers that have been thinned down to a thickness in a range from 50 μm to 100 μm. However, wafers having a thickness equal to or smaller than 100 μm are more difficult to handle than wafers having a thickness larger than 100 μm because they are more susceptible to damage during delivery after being thinned down.

In view of the above difficulty, there has been known in the art a process of grinding the reverse side of a wafer while the face side, i.e., a device side, of the wafer is affixed to a support plate of glass, also referred to as a support substrate or a carrier wafer, for example, by an organic adhesive such as an ultraviolet-curable resin (see, for example, JP 2015-222755A).

After the reverse side of the wafer has been ground, the support plate is peeled off from the wafer after ultraviolet rays have been applied to the adhesive to reduce its bonding strength. While being delivered after the thinning process, the wafer is prevented from being damaged, and the thinned-down wafer peeled off from the support plate can be processed in a subsequent process.

However, the method disclosed in JP 2015-222755A is problematic in that the adhesive tends to remain unremoved on the face side of the thinned-down wafer peeled off from the support plate. It has been proposed in the art to form an annular recess, i.e., a bottomed annular slot, in an outer circumferential region of the support plate that is aligned with an excess outer circumferential region of the wafer, supply the annular recess with an adhesive, and affix the wafer and the support plate to each other with the adhesive (see, for example, JP 2013-026614A).

If the adhesive used in the process disclosed in JP 2013-026614A includes an ultraviolet-curable resin, then it is necessary to apply ultraviolet rays to the adhesive in order to reduce the bonding strength of the adhesive at the time the wafer is to be peeled off from the support plate.

However, since wafers of monocrystalline silicon are almost impermeable to ultraviolet rays, material constraints are imposed on the support plate because it needs to be made of a material such as glass that is permeable to ultraviolet rays, instead of monocrystalline silicon.

If a thermosetting resin is used as the adhesive, then it would make it possible to use another process called a laser debonding process that reduces the bonding strength of the adhesive by irradiating the adhesive with a laser beam in an ultraviolet wavelength band. However, the laser beam in the ultraviolet wavelength band still imposes material constraints on the wafer carrier because the wafer carrier needs to be made of a material such as glass that is permeable to ultraviolet rays.

### SUMMARY OF THE INVENTION

The present invention has been made in view of the foregoing problems. It is an object of the present invention to provide a processing method that reduces constraints on the materials of an adhesive and a support plate providing after a wafer and the support plate have been affixed to each other by using an adhesive, the wafer is separated from the support plate.

In accordance with an aspect of the present invention, there is provided a processing method of processing a device wafer having on a face side thereof a device region where devices have been formed and an excess outer circumferential region surrounding the device region. The method includes forming a recess circumferentially along a support plate including a face having a size equal to or larger than a diameter of the device region and supporting the device wafer, in an outer circumferential region of the face that is positioned outwardly of a central region thereof that is commensurate with the device region, or circumferentially along the device wafer in the excess outer circumferential region of the face side of the device wafer, supplying the recess with resin, affixing the face of the support plate and the face side of the device wafer to each other with use of at least the resin, thereby forming a stack, thinning down the device wafer by grinding or polishing or by grinding and polishing a reverse side of the device wafer that is positioned opposite the face side of the device wafer in a thicknesswise direction thereof, removing a region of the resin that contributes to the affixing of the device wafer and the support plate to each other circumferentially along the device wafer, thereby to reduce a bonding force with which the device wafer and the support plate are bonded to each other in a thicknesswise direction of the stack, or forming an annular slot in the device wafer that extends from the face side to the reverse side thereof outwardly of the device region and inwardly of an annular region aligned with the recess, thereby to sever a portion of the device wafer that includes the device region from the support plate, and separating the portion of the device wafer that includes the device region from the support plate.

Preferably, the processing method further includes, before the stack is formed, forming an additional recess circumferentially in the excess outer circumferential region or the outer circumferential region, which is free of the recess, of the face of the support plate and the face side of the device wafer, and before the stack is formed, supplying the additional recess with an additional resin.

Preferably, in supplying the recess with the resin, while a lower end of a cutting blade is positioned at a first depth from the reverse side of the device wafer or at a second depth from another face of the support plate that is positioned opposite the face of the support plate in a thicknesswise direction thereof, the region of the resin that contributes to the affixing of the device wafer and the support plate to each other is removed by the cutting blade circumferentially along the device wafer, thereby reducing the bonding force with which the device wafer and the support plate are bonded to each other in the thicknesswise direction of the stack.

In supplying the recess with the resin, a pulsed layer beam having a wavelength absorbable by the device wafer may be applied from the reverse side of the device wafer to another face of the support plate that is positioned opposite the face of the support plate in a thicknesswise direction thereof or from the other face of the support plate to the reverse side of the device wafer, thereby to remove the region of the resin that contributes to the affixing of the device wafer and the support plate to each other circumferentially along the device wafer, thereby reducing the bonding force with which the device wafer and the support plate are bonded to each other in the thicknesswise direction of the stack.

In thinning down the device wafer, a central portion of the reverse side of the device wafer that is commensurate with the device region may be thinned down to form a ring-shaped stiffener on an outer circumferential portion thereof that is commensurate with the excess outer circumferential region, and in reducing the bonding force with which the device wafer and the support plate are bonded to each other or in severing the portion of the device wafer from the support plate, the region of the resin that contributes to the affixing of the device wafer and the support plate to each other may be removed circumferentially along the device wafer to reduce the bonding force with which the device wafer and the support plate are bonded to each other in the thicknesswise direction of the stack.

Preferably, while the support plate is held on a holding table and the device wafer is held on a holding plate different from the holding table, the bonding force with which the device wafer and the support plate are bonded to each other is reduced or the portion of the device wafer is severed from the support plate.

Preferably, the support plate includes a plurality of pores extending therethrough from the central region of the face thereof along a thicknesswise direction of the support plate to another face of the support plate that is positioned opposite the face thereof, and in forming the stack, the face of the support plate and the face side of the device wafer are affixed to each other.

In the processing method according to the aspect of the present invention, since the face of the support plate and the face side of the device wafer are affixed to each other using the resin supplied to the recess in the outer region of the support plate or in the excess outer circumferential region of the face side of the device wafer, there is no adhesive left in the device region of the device wafer peeled off from the support plate.

Moreover, the processing method includes removing the region of the resin that contributes to the affixing of the device wafer and the support plate to each other, thereby to reduce the bonding force with which the device wafer and the support plate are bonded to each other, or forming the annular slot in the device wafer that extends from the face side to the reverse side thereof outwardly of the device region and inwardly of the annular region aligned with the recess, thereby to sever the portion of the device wafer that includes the device region from the support plate.

Consequently, the support plate can be peeled off from the device wafer without applying a laser beam having an ultraviolet wavelength band through the support plate to an adhesive. The adhesive and the support plate are thus less liable to suffer material constraints than with the related art.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flowchart of a processing method according to a first embodiment of the present invention;

FIG. 2A is a perspective view of a device wafer;

FIG. 2B is a perspective view of a support plate;

FIG. 3 is an enlarged fragmentary cross-sectional view taken along line A-A of FIG. 2B, illustrating an outer circumferential edge portion of the support plate;

FIG. 4 is a perspective view illustrating a recess forming step of the processing method according to the first embodiment;

FIG. 5 is a side elevational view, partly in cross section, illustrating the recess forming step;

FIG. 6A is a cross-sectional view of the support plate that has undergone the recess forming step;

FIG. 6B is a side elevational view, partly in cross section, illustrating a resin supplying step of the processing method according to the first embodiment;

FIG. 7A is a side elevational view, partly in cross section, illustrating an affixing step of the processing method according to the first embodiment;

FIG. 7B is a side elevational view, partly in cross section, of a stack according to the first embodiment;

FIG. 8A is a perspective view illustrating a thinning step of thinning down the device wafer by way of in-feed grinding;

FIG. 8B is a cross-sectional view of the device wafer that has been ground;

FIG. 9 is a perspective view illustrating a thinning step of thinning down the device wafer by way of polishing;

FIG. 10 is a side elevational view, partly in cross section, illustrating a resin removing step in a separation preparing step of the processing method according to the first embodiment;

FIG. 11 is a side elevational view, partly in cross section, illustrating a separating step;

FIG. 12 is a side elevational view, partly in cross section, illustrating a resin removing step according to a first modification of the first embodiment;

FIG. 13 is a side elevational view, partly in cross section, illustrating a recess in a support plate according to a second modification of the first embodiment;

FIG. 14A is a perspective view illustrating a recess forming step of a processing method according to a second embodiment of the present invention;

FIG. 14B is a side elevational view, partly in cross section, illustrating a resin supplying step of the processing method according to the second embodiment;

FIG. 15 is a flowchart of a processing method according to a third embodiment of the present invention;

FIG. 16A is a side elevational view, partly in cross section, illustrating an affixing step of the processing method according to the third embodiment;

FIG. 16B is a side elevational view, partly in cross section, of a stack according to the third embodiment;

FIG. 17 is a side elevational view, partly in cross section, illustrating an annular groove forming step in a separation preparing step of a processing method according to a fourth embodiment of the present invention;

FIG. 18A is a side elevational view, partly in cross section, illustrating the manner in which a laser beam is applied in a resin removing step of a processing method according to a fifth embodiment of the present invention;

FIG. 18B is a side elevational view, partly in cross section, illustrating the manner in which the laser beam is applied in the resin removing step of the processing method according to a modification of the fifth embodiment;

FIG. 19 is a side elevational view, partly in cross section, illustrating a thinning step of a processing method according to a sixth embodiment of the present invention;

FIG. 20 is a side elevational view, partly in cross section, illustrating a stack that has undergone the thinning step of the processing method according to the sixth embodiment;

FIG. 21 is a side elevational view, partly in cross section, illustrating a resin removing step in a separation preparing step of the processing method according to the sixth embodiment;

FIG. 22A is a plan view of a support plate according to a modification; and

FIG. 22B is an enlarged fragmentary cross-sectional view taken along line B-B of FIG. 22A.

### DETAILED DESCRIPTION OF THE PREFERRED EMBODIMENTS

### First Embodiment

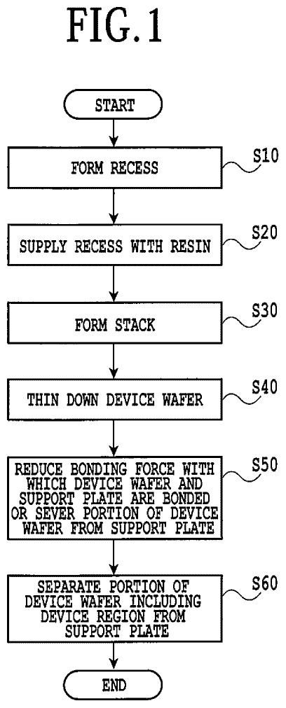

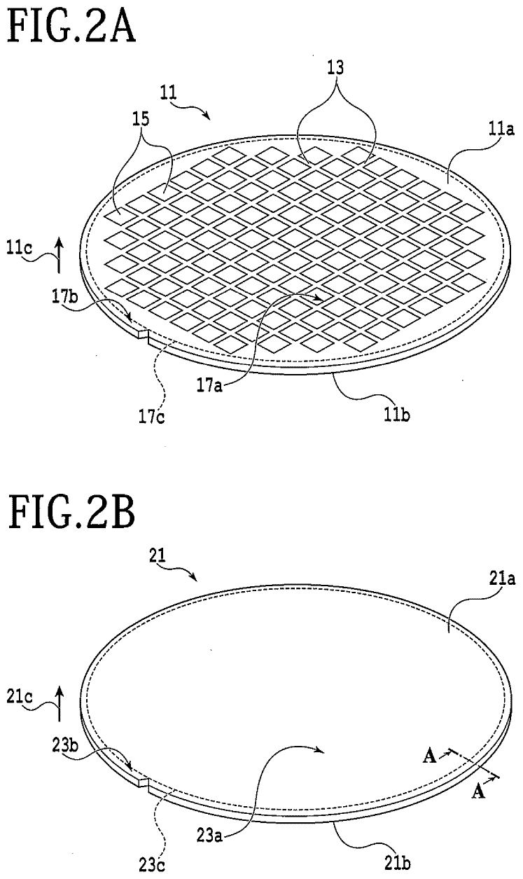

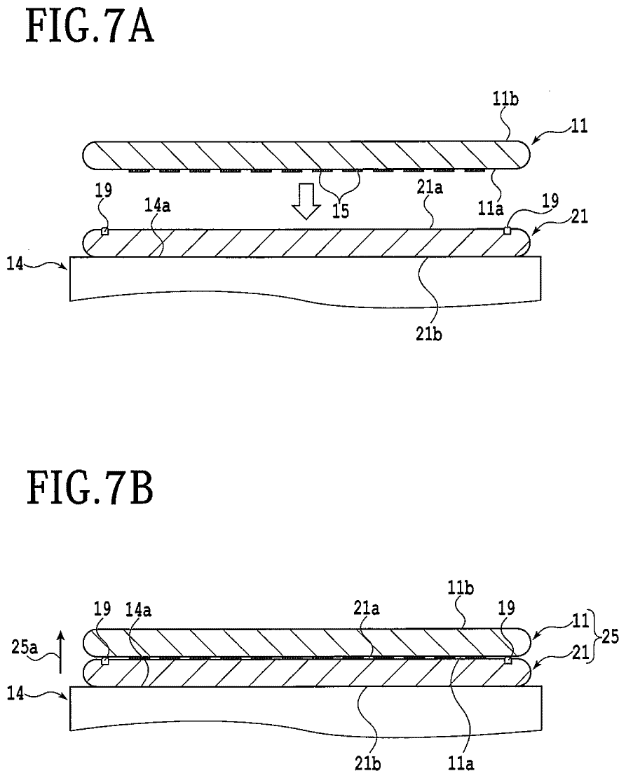

A processing method according to a first embodiment of the present invention will be described in detail below with reference to the accompanying drawings. FIG. 1 is a flowchart of the processing method according to the first embodiment for processing a device wafer 11 (see FIG. 2A). As illustrated in FIG. 1, the processing method according to the first embodiment includes step S10 of forming a recess (recess forming step), step S20 of supplying the recess with resin (resin supplying step), step S30 of forming a stack (i.e., a laminated assembly) 25 (see FIG. 7B) (affixing step), step S40 of thinning down the device wafer 11 (thinning step), step S50 of reducing the bonding strength between the device wafer 11 and a support plate 21 (see FIG. 2B) or separating part of the device wafer 11 from the support plate 21 (separation preparing step), and step S60 of separating part of the device wafer 11 including a device region from the support plate 21 (separating step). These steps are carried out in the order named.

The steps of the processing method according to the first embodiment will be described below. First, the device wafer 11 will be described below with reference to FIG. 2A. FIG. 2A illustrates the device wafer 11 in perspective. The device wafer 11 has a disk-shaped, i.e., plate-shaped, substrate made of monocrystalline silicon (Si), also referred to as a silicon wafer. The substrate of monocrystalline silicon has a thickness ranging from approximately 250 μm to approximately 800 μm depending on the diameter thereof.

The substrate of the device wafer 11 is not limited to any particular materials, types, sizes among others. For example, the device wafer 11 may have a monocrystalline substrate made of any of other semiconductor materials than silicon that include gallium nitride (GaN), silicon carbide (SiC), diamond, and gallium oxide (Ga₂O₃).

The device wafer 11 has a face side 11a with a grid of projected dicing lines or streets 13 established thereon along which the device wafer 11 will be divided. The projected dicing lines 13 demarcate a plurality of rectangular areas on the face side 11a where respective devices 15 such as ICs are constructed. The devices 15 are not limited to any particular types, numbers, shapes, structures, sizes, and layouts, for example.

According to the present embodiment, the face side 11a includes a central region referred to as a device region 17a. The device region 17a includes a circular region on the face side 11a that contains all the devices 15 and that extends radially outwardly but terminates short of an outer circumferential edge portion of the device wafer 11.

According to the present embodiment, furthermore, the face side 11a also includes an annular region radially surrounding the device region 17a and extending to an outer circumferential edge of the device wafer 11. The annular region is referred to an outer circumferential edge portion 17b. In FIG. 2A, an annular boundary 17c between the device region 17a and the outer circumferential edge portion 17b is indicated by the broken line. The boundary 17c is depicted only for illustrative purposes in FIG. 2A and actually not plotted on the face side 11a.

The device wafer 11 has a reverse side 11b opposite the face side 11a across its thickness along a thicknesswise direction 11c. The substrate of monocrystalline silicon is exposed on the reverse side 11b. Prior to thinning step S40 of thinning down the device wafer 11 by grinding or polishing or by grinding and polishing the reverse side 11b, the device wafer 11 and the support plate 21 (see FIG. 2B) are affixed to each other.

FIG. 2B illustrates the support plate 21 in perspective. The support plate 21 has a disk-shaped substrate of monocrystalline silicon, i.e., a silicon wafer, such as a dummy wafer, a test wafer, or a mirror wafer. The support plate 21 is free of devices 15. The material of the support plate 21 is not limited to a substrate of monocrystalline silicon and may be any of other materials than monocrystalline silicon, including ceramic, glass, resin, or metal, for example.

The material of the support plate 21 may be either permeable or impermeable to ultraviolet rays or radiations in other wavelength bands than ultraviolet rays. According to the present embodiment, material constraints imposed on the support plate 21 are thus reduced, and material constraints imposed on an adhesive used to bond the device wafer 11 and the support plate 21 to each other are reduced.

The support plate 21 is not limited to any particular thicknesses, but should preferably have a thickness in excess of 100 μm, e.g., a thickness of 1.0 mm, to make itself rigid to a certain degree. The support plate 21 has a circular face 21a and another circular face 21b that are opposite each other across its thickness along a thicknesswise direction 21c.

The face 21a has a diameter, i.e., a size, equal to or larger than the diameter of the device region 17a of the device wafer 11. According to the present embodiment, the diameter of the face 21a is substantially the same as the diameter of the face side 11a. However, if the support plate 21 has a rectangular substrate, then each of the sides of the face 21a may be equal to or larger than the diameter of the device region 17a in order to enable the face 21a to keep the face side 11a in its entirety thereon.

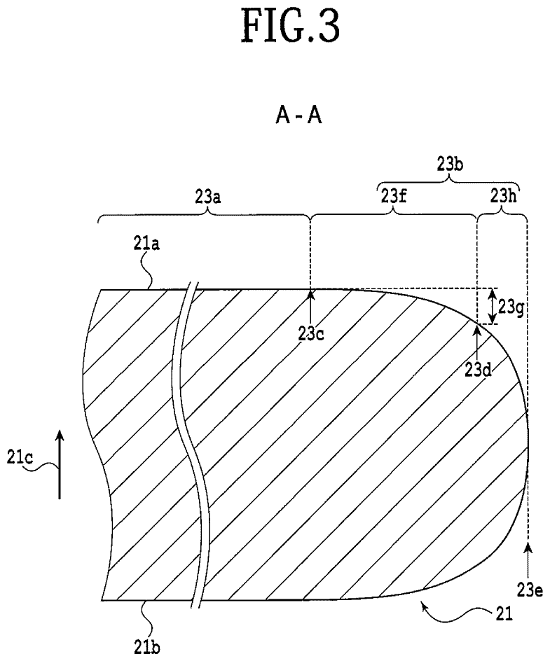

The face 21a has a circular central region 23a that is commensurate with the device region 17a. The central region 23a is equal in diameter to the device region 17a. According to the present embodiment, an annular region of the face 21a that is positioned radially outwardly of the central region 23a and extends radially outwardly to an outer circumferential edge 23e (see FIG. 3) of the support plate 21 is referred to as an outer circumferential region 23b.

In FIG. 2B, an annular boundary 23c between the central region 23a and the outer circumferential region 23b is indicated by the broken line in FIG. 2B only for illustrative purposes. Actually, the boundary 23c is not plotted on the support plate 21.

FIG. 3 illustrates, in enlarged fragmentary cross section, an outer circumferential edge portion of the support plate 21, taken along line A-A of FIG. 2B. In FIG. 3, the outer circumferential edge 23e of the support plate 21, a position 23d on the face 21a that is spaced radially inwardly from the outer circumferential edge 23e by a predetermined distance of 1 mm, for example, and the boundary 23c are also depicted.

An annular region extending radially outwardly from the boundary 23c to the predetermined position 23d is less planar than the central region 23a of the face 21a, and the shape of the annular region is called “edge roll-off.” According to the present embodiment, the annular region is referred to as a “roll-off region 23f.”

A distance 23g that extends along the thicknesswise direction 21c from the predetermined position 23d to an imaginary plane, indicated by the broken line in FIG. 3, parallel to the face 21a of the support plate 21 is occasionally used as an index representing the planarity of the roll-off region 23f (roll-off amount: ROA).

According to the present embodiment, another annular region extending radially outwardly from the predetermined position 23d to the outer circumferential edge 23e is referred to as a “beveled region 23h.” The roll-off region 23f and the beveled region 23h jointly make up the outer circumferential region 23b. The outer circumferential edge portion 17b of the face side 11a of the device wafer 11 is also of a cross-sectional shape similar to the cross-sectional shape of the roll-off region 23f and the beveled region 23h. Annular regions of the reverse side 11b that correspond to the outer circumferential edge portion 17b along the thicknesswise direction 11c are of a similar cross-sectional shape.

In a case where the support plate 21 has a substrate of monocrystalline silicon such as a dummy wafer, for example, the support plate 21 usually has the roll-off region 23f and the beveled region 23h. However, support plates 21 made of other materials and/or having other shapes may not necessarily have the roll-off region 23f and the beveled region 23h.

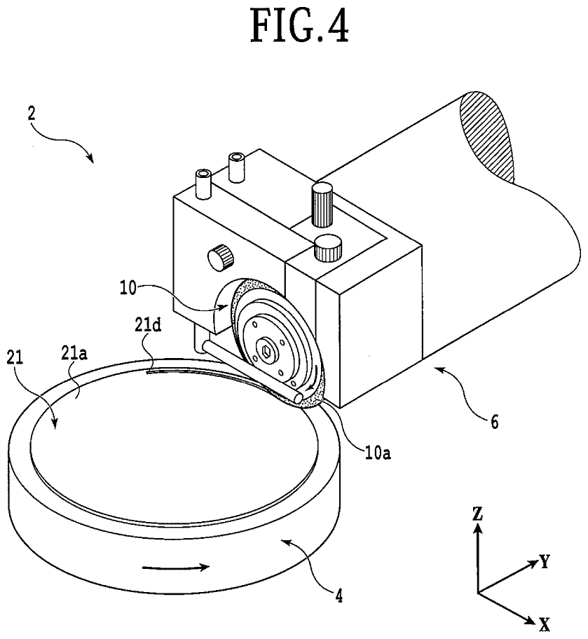

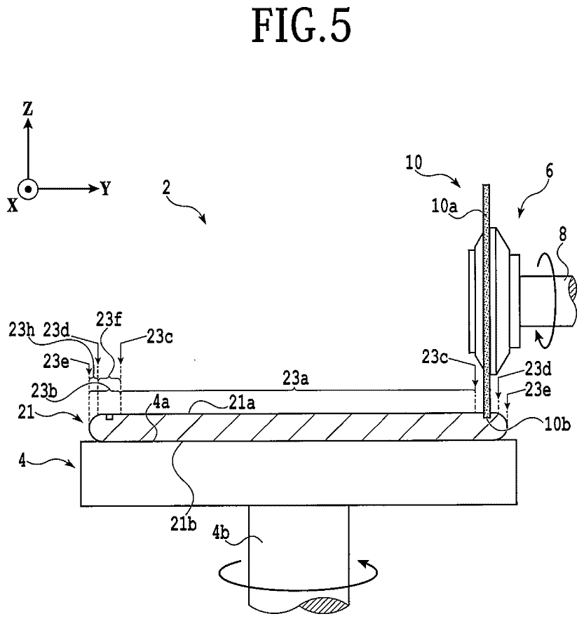

Recess forming step S10 will be described below with reference to FIGS. 4 and 5. FIG. 4 illustrates recess forming step S10 in perspective, and FIG. 5 illustrates recess forming step S10 in side elevation, partly in cross section. An X-axis extending horizontally that is indicated by an arrow X, a Y-axis extending horizontally that is indicated by an arrow Y, and a Z-axis extending vertically that is indicated by an arrow Z, are illustrated in FIGS. 4 and 5 and extend perpendicularly to each other.

In recess forming step S10 according to the present embodiment, a cutting apparatus 2 is used to form an annular recess 21d extending circumferentially in the roll-off region 23f of the support plate 21. The cutting apparatus 2 includes a disk-shaped chuck table 4 having a disk-shaped frame made of metal.

The frame has a cavity defined diametrically centrally therein that is smaller in diameter than the frame. A disk-shaped porous plate, not depicted, made of porous ceramic is fixed fitted in the cavity. The frame and the porous plate have respective upper surfaces that are exposed upwardly and lie substantially flush with each other, jointly providing a substantially flat upper holding surface 4a (see FIG. 5).

The holding surface 4a lies substantially parallel to an XY plane that is defined along the X-axis and the Y-axis. The porous plate is fluidly connected to a suction source, not depicted, such as a vacuum pump, for example. When the suction source is actuated, it generates and transmits a negative pressure to the porous plate, thereby creating a suction force on the holding surface 4a. The chuck table 4 has a lower surface whose central portion is fixed to the upper end of a rotational shaft 4b (see FIG. 5) extending substantially parallel to the Z-axis.

The rotational shaft 4b has a lower end connected to a rotary actuator, not depicted, such as an electric motor. When the rotary actuator is energized, it rotates the rotational shaft 4b about its vertical central axis, rotating the chuck table 4 about its central axis aligned with the vertical central axis of the rotational shaft 4b. The chuck table 4 and the rotational shaft 4b are movable in unison horizontally along the X-axis by a moving mechanism, not depicted, that includes a ball screw.

The cutting apparatus 2 also includes a cutting unit 6 disposed above the holding surface 4a of the chuck table 4. The cutting unit 6 has a cylindrical spindle 8 (see FIG. 5) whose longitudinal central axis extends horizontally along the Y-axis. The spindle 8 has a proximal end portion, not depicted, connected to rotary actuator, not depicted, such as an electric motor. The spindle 8 has a distal end portion on which there is mounted a cutting blade 10 having an annular cutting edge 10a. When the rotary actuator is energized, it rotates the spindle 8 about its longitudinal central axis and hence the cutting blade 10 about its horizontal central axis aligned with the longitudinal central axis of the spindle 8, rotating the cutting edge 10a about its central axis aligned with the horizontal central axis of the cutting blade 10. The cutting unit 6 is movable along the Y-axis and the Z-axis by a moving mechanism, not depicted, that includes a ball screw.

The cutting apparatus 2 is controlled in operation by a controller, not depicted. The controller includes a computer including a processor, typically, a central processing unit (CPU), a main storage device such as a dynamic random access memory (DRAM), and an auxiliary storage device such as a solid-state drive. The auxiliary storage device stores software including certain programs. The processor is operated according to the software to enable the controller to perform its functions.

In recess forming step S10, as illustrated in FIGS. 4 and 5, the face 21a of the support plate 21 is exposed upwardly and the other face 21b thereof is put in contact with the holding surface 4a of the chuck table 4. Then, the support plate 21 is held under suction on the chuck table 4 by the suction force created on the holding surface 4a.

Thereafter, the spindle 8 is rotated about its longitudinal central axis at a predetermined rotational speed, and the cutting unit 6 is lowered from above the support plate 21, causing the cutting edge 10a to cut into the roll-off region 23f on the face 21a, i.e., to make a chopper cut. At this time, the cutting edge 10a has a lower end 10b whose position is appropriately adjusted depending on the depth of the recess 21d to be formed in the roll-off region 23f. The recess 21d has a width in the radial directions of the face 21a that is equal to the thickness of the cutting edge 10a.

The rotational shaft 4b is turned about the vertical central axis thereof through a predetermined angle per unit time. At least while the chuck table 4 makes one revolution, the cutting unit 6 is fixed in position vertically along the Z-axis, cutting the support plate 21 to form the recess 21d to a predetermined depth in the roll-off region 23f.

During the cutting process, cutting water such as pure water is supplied at a predetermined flow rate to an area where the cutting edge 10a and the support plate 21 are kept in contact with each other. An example of cutting conditions is given below. The width of the recess 21d may be made larger than the thickness of the cutting edge 10a by changing the position of the cutting unit 6 along the Y-axis with respect to the holding surface 4a between the first revolution of the chuck table 4 and the second or subsequent revolution thereof.
Rotational speed of cutting blade: 20000 rpm
Angle through which chuck table is turned per unit time: 5°/s
Flow rate of cutting water: 5 L/min
Depth of recess: 0.04 mm to 0.40 mm from vertical position of central region 23a
Width of recess: 1.0 mm to 3.0 mm

Instead of making the chopper cut, the chuck table 4 may be moved along the X-axis while the lower end 10b of the rotating cutting edge 10a is fixed in position along the Z-axis, causing the cutting edge 10a to cut to a desired position in the roll-off region 23f, after which the chuck table 4 may start rotating about its vertical central axis.

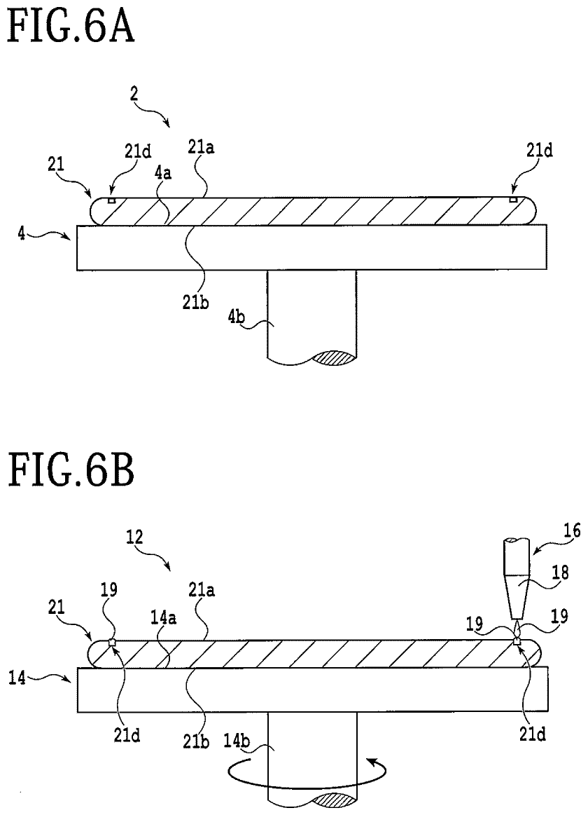

Resin supplying step S20 will be described below. FIG. 6A illustrates, in cross section, the support plate 21 that has undergone recess forming step S10. After recess forming step S10, an affixing apparatus 12 (see FIG. 6B) is used to supply a liquid resin 19 to the recess 21d (resin supplying step S20). The affixing apparatus 12 has a disk-shaped chuck table 14 (see FIG. 6B).

The chuck table 14 is essentially identical in structure and shape to the chuck table 4 of the cutting apparatus 2, and will be omitted from detailed description. The chuck table 14 has an upper holding surface 14a and a rotational shaft 14b.

As illustrated in FIG. 6B, the affixing apparatus 12 includes a dispenser unit 16 disposed above the chuck table 14. The dispenser unit 16 includes a needle 18 for discharging the liquid resin 19. The liquid resin 19 is discharged from the needle 18 at a flow rate controlled by a controller, not depicted, of the dispenser unit 16. The controller includes an electric circuit, not depicted.

The controller outputs an electric signal for controlling the opening and closing of a valve, not depicted, on a pipe interconnecting a tank, not depicted, that is filled with compressed air and a syringe, not depicted, filled with the liquid resin 19. The controller controls the timing of opening and closing of the valve thereby to control the rate at which the liquid resin 19 is discharged from the needle 18. Alternatively, while the liquid resin 19 that has filled a tank is delivered under pressure to the valve, the controller may control the opening and closing of the valve thereby to control the rate at which the liquid resin 19 is discharged from the needle 18.

According to the present embodiment, the liquid resin 19 includes a thermosetting epoxy resin. However, the liquid resin 19 may include another resin such as an acrylic resin, for example. The liquid resin 19 is not limited to a thermosetting epoxy resin but may be resin 19 that is curable by way of solvent evaporation or exposure to ultraviolet rays.

FIG. 6B illustrates resin supplying step S20 in side elevation, partly in cross section. In resin supplying step S20, while the needle 18 has its lower opening facing the recess 21d, the liquid resin 19 is supplied from the opening of the needle 18 to the recess 21d at the same time that the chuck table 14 is turned about its vertical central axis through a predetermined angle per unit time.

The liquid resin 19 is supplied to fill the recess 21d preferably to the extent that the liquid resin 19 will finally be slightly convex, i.e., slightly protrusive, from the face 21a of the support plate 21. The total amount of the liquid resin 19 thus supplied is appropriately adjusted to affix the face side 11a of the device wafer 11 and the face 21a of the support plate 21 to each other without the liquid resin 19 reaching the device region 17a when the face side 11a is held against the face 21a.

After resin supplying step S20, the chuck table 14 is moved to a predetermined position by a moving mechanism. After the position of the support plate 21 has been finely adjusted using a camera in that position, a suction holding unit, not depicted, that is holding the device wafer 11 under suction is lowered as illustrated in FIG. 7A.

As described above, the liquid resin 19 includes a thermosetting epoxy resin according to the present embodiment. After the face side 11a has contacted the liquid resin 19 in the recess 21d, a heat source, not depicted, such as a resistance heater that may be embedded in the chuck table 14 is energized to cure the liquid resin 19. When the liquid resin 19 is cured, it bonds the device wafer 11 and the support plate 21 to each other.

FIG. 7A illustrates affixing step in side elevation, partly in cross section. FIG. 7B illustrates the stack 25 produced in affixing step S30 in side elevation, partly in cross section. As illustrated in FIG. 7B, the face 21a of the support plate 21 and the face side 11a of the device wafer 11 are affixed to each other by at least the cured resin 19, making up the stack 25.

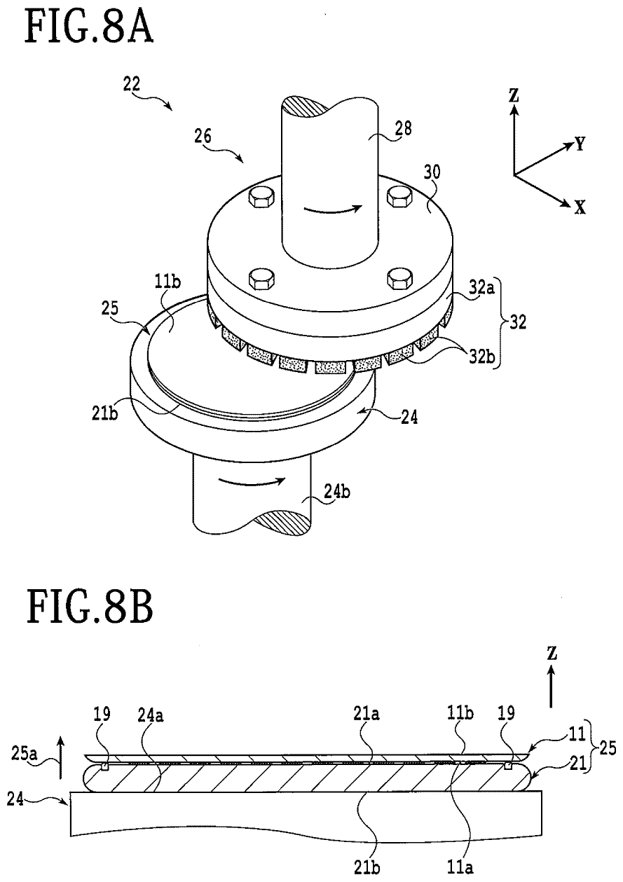

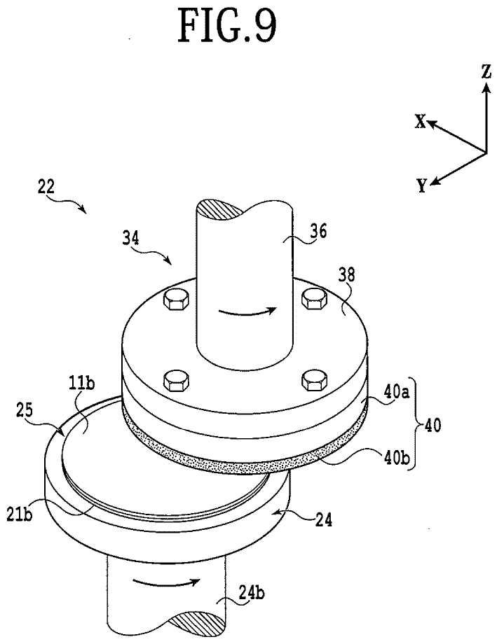

In the stack 25, the device wafer 11 is supported on the support plate 21. Even when the device wafer 11 is thinned down subsequently in thinning step S40, the stack 25 remains rigid enough because of the support plate 21 included therein. According to the present embodiment, after affixing step S30, a grinding and polishing apparatus 22 (see FIGS. 8A, 8B, and 9) is used to grind and polish the reverse side 11b of the device wafer 11, thereby thinning down the device wafer 11.

The grinding and polishing apparatus 22 will be described below with reference to FIGS. 8A, 8B, and 9. An X-axis extending horizontally that is indicated by the arrow X, a Y-axis extending horizontally that is indicated by the arrow Y, and a Z-axis extending vertically that is indicated by the arrow Z, are illustrated in FIGS. 8A, 8B, and 9 and extend perpendicularly to each other. The grinding and polishing apparatus 22 includes a disk-shaped chuck table 24 having a disk-shaped frame made of dense ceramic.

The frame has a cavity defined diametrically centrally therein that is smaller in diameter than the frame. A disk-shaped porous plate, not depicted, made of porous ceramic is fixed fitted in the cavity. The frame and the porous plate have respective upper surfaces that are exposed upwardly and lie substantially flush with each other, jointly providing a substantially flat upper holding surface 24a (see FIG. 8B). The holding surface 24a is of an upwardly protruding conical shape including a central portion that protrudes slightly upwardly beyond an outer circumferential portion thereof by a very small distance ranging from approximately 10 μm to approximately 30 μm. In FIG. 8B, therefore, the holding surface 24a is illustrated essentially flatwise.

The porous plate is fluidly connected to a suction source, not depicted, such as a vacuum pump, for example. When the suction source is actuated, it generates and transmits a negative pressure to the porous plate through the frame, thereby creating a suction force on the holding surface 24a. The chuck table 24 has a lower surface whose central portion is fixed to the upper end of a rotational shaft 24b extending substantially parallel to the Z-axis.

The rotational shaft 24b has a lower end connected to a rotary actuator, not depicted, such as an electric motor. When the rotary actuator is energized, it rotates the rotational shaft 24b about its vertical central axis, rotating the chuck table 24 about its central axis aligned with the vertical central axis of the rotational shaft 24b. The rotational shaft 24b is slightly inclined such that a portion of the holding surface 24a that is commensurate with a processed region of the device wafer 11 lies substantially parallel to an XY plane that is defined along the X-axis and the Y-axis. The grinding and polishing apparatus 22 includes a grinding unit 26 (see FIG. 8A) disposed above the holding surface 24a.

The grinding unit 26 has a cylindrical spindle 28 whose longitudinal central axis extends vertically along the Z-axis. A rotary actuator, not depicted, such as an electric motor is coupled to a longitudinally central portion of the spindle 28. The spindle 28 has a lower end to which a disk-shaped wheel mount 30 is fixed.

A disk-shaped grinding wheel 32 is mounted on the lower surface of the wheel mount 30. The grinding wheel 32 has an annular base 32a of metal that has a lower surface on which there is mounted an annular array of grindstones 32b spaced at substantially equal angular intervals circumferentially along the base 32a. The grinding and polishing apparatus 22 further includes a polishing unit 34 (see FIG. 9) disposed near the grinding unit 26.

The polishing unit 34 has a cylindrical spindle 36 whose longitudinal central axis extends vertically along the Z-axis. A rotary actuator, not depicted, such as an electric motor is coupled to a longitudinally central portion of the spindle 36. The spindle 36 has a lower end to which a disk-shaped wheel mount 38 is fixed.

A disk-shaped polishing tool 40 is mounted on the lower surface of the wheel mount 38. The polishing tool 40 has a disk-shaped base 40a of metal that has a lower surface to which a polishing pad 40b is fixed. The polishing pad 40b includes a polishing pad of bonded abrasive grains. For example, the polishing pad 40b has a base member made of foamed hard polyurethane, for example, and abrasive grains made of silica, for example, bonded to and in the base member.

The polishing tool 40 has a through hole, not depicted, defined diametrically centrally therein and extending through the base 40a and the polishing pad 40b along the Z-axis. While the grinding and polishing apparatus 22 is polishing the reverse side 11b of the device wafer 11, a polishing liquid suitable for the polishing of the workpiece to be polished, i.e., the device wafer 11, is supplied via the through hole to the reverse side 11b.

Thinning step S40 will be described below with reference to FIGS. 8A, 8B, and 9. FIG. 8A illustrates, in perspective, thinning step S40 of thinning down the device wafer 11 by way of in-feed grinding. In thinning step S40, the face 21b of the support plate 21 is held under suction on the holding surface 24a such that the face 21a of the support plate 21 is exposed upwardly.

Then, the chuck table 24 is positioned directly below the grinding unit 26, after which the rotational shaft 24b and the spindle 28 are rotated in respective directions and the grinding unit 26 is lowered, i.e., grinding-fed, along the Z-axis at a predetermined speed. While the grinding unit 26 is grinding the device wafer 11, grinding water such as pure water is supplied at a predetermined flow rate to an area where the grindstones 32b and the reverse side 11b are kept in contact with each other.

The grinding process in thinning step S40 includes, for example, a coarse grinding process using a coarse grinding wheel that includes coarse grindstones as the grindstones 32b and a fine grinding process using a fine grinding wheel that includes fine grindstones as the grindstones 32b.

The coarse grindstones have a granularity of #320, for example, whereas the fine grindstones have a granularity of #2000, for example. The granularity represents the size of the abrasive grains. For details of the granularity, reference should be made to JIS R 6001-2:2017 (the granularity of grinding materials for grindstones—part 2: fine powder) of the Japanese Industrial Standards (JIS).

An example of grinding conditions is given below. The length of time during which the coarse grinding process is carried out and the length of time during which the fine grinding process is carried out are determined depending on the thickness of the device wafer 11 to be ground away.

### Coarse Grinding Process:

Rotational speed of spindle: 3200 rpm
Rotational speed of chuck table: 300 rpm
Grinding feed speed: 3.0 μm/s
Flow rate of grinding water: 4.0 L/min

### Fine Grinding Process:

Rotational speed of spindle: 3200 rpm
Rotational speed of chuck table: 300 rpm
Grinding feed speed: 0.3 μm/s
Flow rate of grinding water: 4.0 L/min

After the entire reverse side 11b has been coarsely ground, the fine grinding process is carried out. After the device wafer 11 has been thinned down to a desired thickness by the coarse grinding process and the fine grinding process, the grinding unit 26 is lifted along the Z-axis. FIG. 8B illustrates, in cross section, the device wafer 11 that has been ground.

According to the present embodiment, the reverse side 11b that has been ground is polished. After the reverse side 11b has been ground, the chuck table 24 stops being rotated and is moved to a position directly below the polishing unit 34 (see FIG. 9). FIG. 9 illustrates thinning step S40 of thinning down the device wafer 11 by way of polishing.

During the polishing process, an alkaline aqueous solution is supplied as a polishing liquid at a predetermined flow rate to an area where the polishing pad 40b and the reverse side 11b are kept in contact with each other. At the same time, the polishing pad 40b is pressed against the reverse side 11b of the device wafer 11 on the chuck table 24 under a predetermined pressing force, thereby polishing the reverse side 11b in its entirety.

If no abrasive grains are included in the polishing pad 40b, then the polishing liquid contains abrasive grains. Depending on the material of the workpiece, i.e., the device wafer 11, to be polished, the aqueous solution has its components selected and adjusted appropriately. For example, if the workpiece includes a substrate of monocrystalline silicon carbide, then an acidic aqueous solution is used as the polishing liquid. An example of polishing conditions according to the present embodiment is given below.
Rotational speed of spindle: 750 rpm
Rotational speed of chuck table: 745 rpm
Pressing force: 40 kPa
Flow rate of polishing liquid: 200 mL/min
Polishing period: 620 s

In thinning process S40 according to the present embodiment, the device wafer 11 is both ground and polished. However, depending on the material and thickness of the device wafer 11, the polishing process may be omitted and the device wafer 11 may be only ground or the grinding process may be omitted and the device wafer 11 may be only polished.

After thinning step S40, separation preparing step S50 is carried out using the cutting apparatus 2 described above. Separation preparing step S50 will be described below. According to the present embodiment, separation preparing step S50 includes a step of removing the region of the cured resin 19 that contributes to the affixing of the device wafer 11 and the support plate 21 to each other, thereby reducing the bonding force with which the device wafer 11 and the support plate 21 are bonded to each other along a thicknesswise direction 25a of the stack 25 (resin removing step).

Removing the region of the cured resin 19 that contributes to the affixing of the device wafer 11 and the support plate 21 to each other does not necessarily mean removing the entire resin 19 completely. The region of the cured resin 19 that contributes to the affixing of the device wafer 11 and the support plate 21 to each other can be removed by removing at least the portion of the resin 19 that is held in contact with the face side 11a.

By removing at least the portion of the resin 19 that is held in contact with the face side 11a, the main force involved in bonding the device wafer 11 and the support plate 21 to each other is cancelled. The thickness along the Z-axis of the portion of the resin 19 to be removed may be appropriately determined in view of the accuracy with which the cutting apparatus 2 is able to cut the workpiece and the period of time required for the cutting apparatus 2 to cut the workpiece.

In the resin removing step, the chuck table (holding table) 4 holds the face 21b of the support plate 21 under suction thereon, and a holding plate 42 different from the chuck table 4 holds the reverse side 11b of the device wafer 11 under suction thereon.

The holding plate 42 includes a frame of metal that is smaller in diameter than the chuck table 4. The frame has a disk-shaped cavity, not depicted, defined in a lower surface thereof, and a disk-shaped porous plate, not depicted, is fixedly fitted in the cavity. The frame and the porous plate have respective lower surfaces lying substantially flush with each other, jointly providing a substantially flat holding surface 42a.

The holding surface 42a is substantially equal in diameter to the device region 17a or smaller in diameter than the device region 17a, and lies substantially parallel to the XY plane. The porous plate is fluidly connected to a suction source, not depicted, such as a vacuum pump, for example. When the suction source is actuated, it generates and transmits a negative pressure to the porous plate through the frame, thereby creating a suction force on the holding surface 42a.

A rotational shaft 42b extending substantially parallel to the Z-axis has a lower end fixed centrally to an upper surface of the holding plate 42. The rotational shaft 42b has an upper end connected to a rotary actuator, not depicted, such as an electric motor. When the rotary actuator is energized, it rotates the rotational shaft 42b about its vertical central axis and hence the holding plate 42 about its vertical central axis aligned with the vertical central axis of the rotational shaft 42b. The holding plate 42 and the rotational shaft 42b are movable in unison with each other along at least the Z-axis by a moving mechanism, not depicted, including a ball screw.

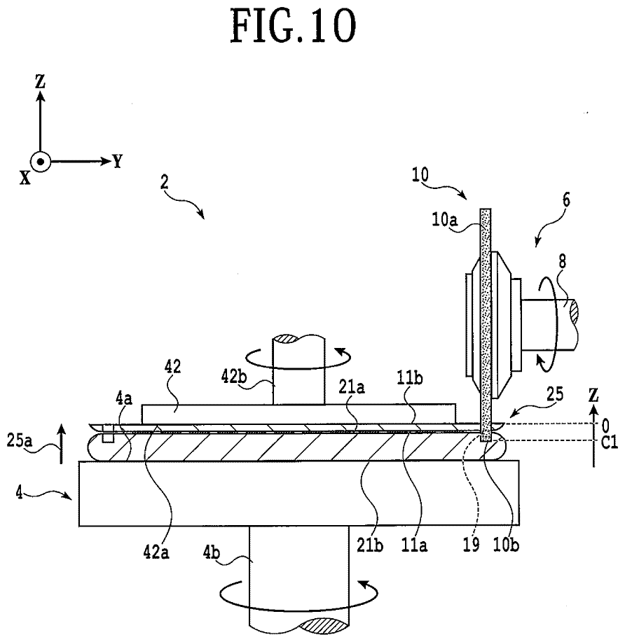

FIG. 10 illustrates the resin removing step in separation preparing step S50 in side elevation, partly in cross section. In the resin removing step according to the present embodiment, first, the face 21b of the support plate 21 is held under suction on the chuck table 4, and the portion of the reverse side 11b of the device wafer 11 that is positioned radially inwardly of the cured resin 19 is held under suction on the holding plate 42.

Then, the spindle 8 is rotated about its longitudinal central axis at a predetermined rotational speed, and the cutting unit 6 is lowered from above the support plate 21, positioning the lower end 10b of the cutting edge 10a at a first depth C1 extending from the reverse side 11b of the device wafer 11 along the Z-axis, i.e., to making a chopper cut.

Instead of making the chopper cut, the chuck table 4 may be moved along the X-axis while the lower end 10b of the rotating cutting edge 10a is fixed at the first depth C1 along the Z-axis, causing the cutting edge 10a to cut to a desired position in the roll-off region 23f, after which the chuck table 4 may start rotating about its vertical central axis.

The position of the lower end 10b of the rotating cutting edge 10a, i.e., the first depth C1, is closer to the face 21a of the support plate 21 than at least the face side 11a of the device wafer 11. According to the present embodiment, the lower end 10b of the cutting edge 10a is positioned within the support plate 21.

With the cutting edge 10a thus cutting into the outer circumferential edge portion 17b of the device wafer 11 and the cured resin 19, the chuck table 4 and the holding plate 42 start being rotated and are turned through the same angle per unit time.

At least while the chuck table 4 makes one revolution, the cutting unit 6 is fixed in position vertically along the Z-axis, removing the region of the resin 19 that contributes to the affixing of the device wafer 11 and the support plate 21 to each other circumferentially along the device wafer 11. In this manner, the region of the resin 19 that contributes to the affixing of the device wafer 11 and the support plate 21 to each other is removed circumferentially along the device wafer 11 by the cutting blade 10. The bonding force with which the device wafer 11 and the support plate 21 are bonded to each other along the thicknesswise direction 25a is now reduced.

At this time, since the device wafer 11 is held under suction on the holding plate 42, the disk-shaped region as the device region 17a is prevented from being separated and scattered from the support plate 21, and the device region 17a is prevented from being cut in error when the device wafer 11 is thus cut.

During the cutting process, cutting water such as pure water is supplied at a predetermined flow rate to an area where the cutting edge 10a and the stack 25 are kept in contact with each other. An example of cutting conditions is given below.
Rotational speed of cutting blade: 20000 rpm
Angle through which chuck table is turned per unit time: 5°/s
Flow rate of cutting water: 5.0 L/min

In separation preparing step S50 according to the present embodiment, the region of the cured resin 19 that contributes to the affixing of the device wafer 11 and the support plate 21 to each other is removed without applying a laser beam in an ultraviolet wavelength band to the adhesive, i.e., the resin 19, through the support plate 21.

Consequently, in subsequent separating step S60, the support plate 21 can be peeled off from the device wafer 11. As there are not constraints that would result from the transmission of ultraviolet rays through the support plate 21, the adhesive and the support plate 21 are less liable to suffer material constraints than with the related art.

According to the present embodiment, the resin removing step in separation preparing step S50 uses the cutting apparatus 2 that is used in recess forming step S10. However, a cutting apparatus including the chuck table 4, the holding plate 42, and the cutting unit 6 but different from the cutting apparatus 2 may be used in the resin removing step. In other words, either the cutting apparatus 2 or another cutting apparatus different from the cutting apparatus 2 may be used in the resin removing step. The other cutting apparatus may use another cutting blade having the same cutting edge thickness as the cutting blade 10 or another cutting blade having a larger cutting edge thickness than the cutting blade 10.

The holding plate 42 may not necessarily be limited to the structure including the frame and the porous plate described above. Rather, the holding plate 42 may have a base member made of metal, resin, or ceramic and one or a plurality of suction pads disposed on a lower surface of the base member for supplying a negative pressure. The stack 25 may be turned upside down, so that the reverse side 11b of the device wafer 11 may be held under suction on the chuck table 4 and the face 21b of the support plate 21 may be held under suction on the holding plate 42.

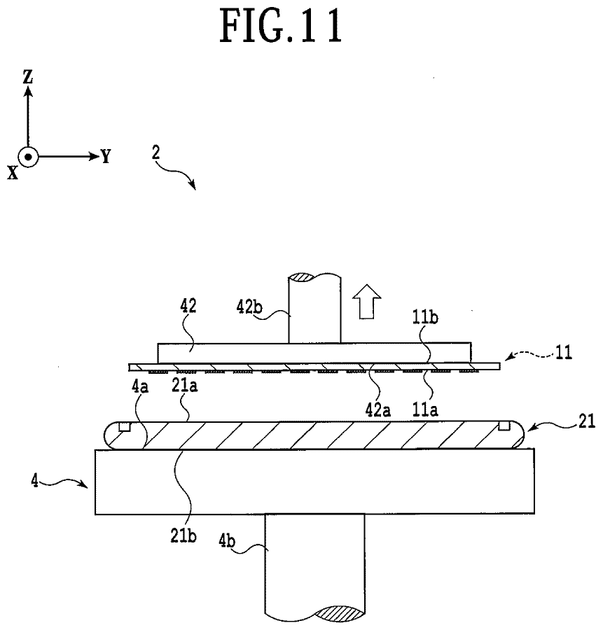

Separation preparing step S50 (resin removing step) is followed by separating step S60. FIG. 11 illustrates separating step S60 in side elevation, partly in cross section. In separating step S60, the holding plate 42 and the rotational shaft 42b are lifted in unison along the Z-axis, separating the remaining portion of the device wafer 11 including the device region 17a from the support plate 21.

In separation preparing step S50, inasmuch as the main force involved in bonding the device wafer 11 and the support plate 21 to each other with the cured resin 19 has already been cancelled, when the remaining portion of the device wafer 11 is lifted, the device wafer 11 including the device region 17a can easily be separated, i.e., peeled off, from the support plate 21.

### First Modification

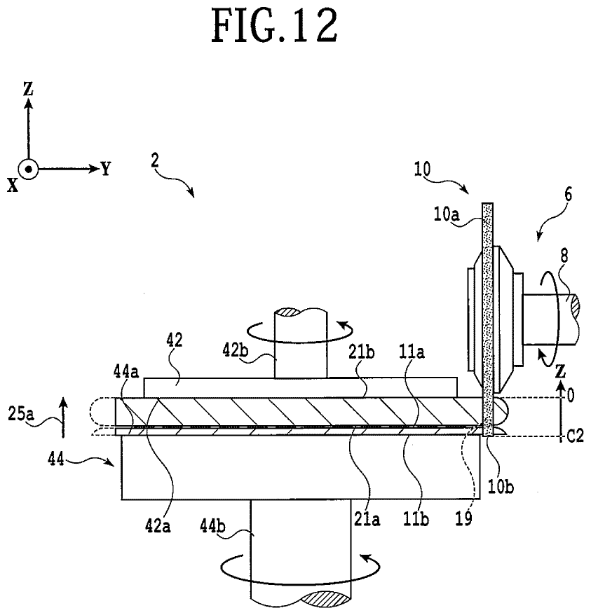

A first modification of the first embodiment will be described below with reference to FIG. 12. According to the first modification, as illustrated in FIG. 12, a chuck table 44 that is equal to or smaller in diameter than the device region 17a is used in a resin removing step. The chuck table 44 has an upper holding surface 44a with a rotational shaft 44b fixed centrally to a lower surface of the chuck table 44.

FIG. 12 illustrates a resin removing step (separation preparing step S50) according to the first modification of the first embodiment. In the resin removing step according to the first modification, the central portion of the reverse side 11b of the device wafer 11 is held under suction on the chuck table 44, and the central portion of the face 21b of the support plate 21 is held under suction on the holding plate 42.

Then, the spindle 8 is rotated about its longitudinal central axis at a predetermined rotational speed, and the cutting unit 6 is lowered from above the support plate 21, positioning the lower end 10b of the cutting edge 10a at a second depth C2 extending from the face 21b of the support plate 21 along the Z-axis, i.e., to make a chopper cut. According to the first modification, the second depth C2 is positioned beneath the holding surface 44a along the Z-axis.

With the cutting edge 10a thus cutting into the outer circumferential edge portion 17b of the device wafer 11 and the cured resin 19, the chuck table 44 and the holding plate 42 are turned through the same angle per unit time, removing the region of the resin 19 that contributes to the affixing of the device wafer 11 and the support plate 21 to each other circumferentially along the device wafer 11 with the cutting blade 10.

By thus simultaneously cutting the outer circumferential region 23b of the support plate 21 and the outer circumferential edge portion 17b of the device wafer 11, the outer circumferential edge portion 17b of the device wafer 11 and the outer circumferential region 23b of the support plate 21 are severed in the thicknesswise direction 25a. As a result, the bonding force with which the device wafer 11 and the support plate 21 are bonded to each other along the thicknesswise direction 25a of the stack 25 is reduced.

Instead of making the chopper cut, the chuck table 44 may be moved along the X-axis while the lower end 10b of the rotating cutting edge 10a is fixed in the second depth C2 along the Z-axis, causing the cutting edge 10a to cut to a desired position in the roll-off region 23f, after which the chuck table 44 may start rotating about its vertical central axis. Moreover, the outer circumferential edge portion 17b and the outer circumferential region 23b may be cut away by a cutting blade, not depicted, having a cutting edge thickness that is substantially the same as the respective width of the outer circumferential edge portion 17b and the outer circumferential region 23b.

### Second Modification

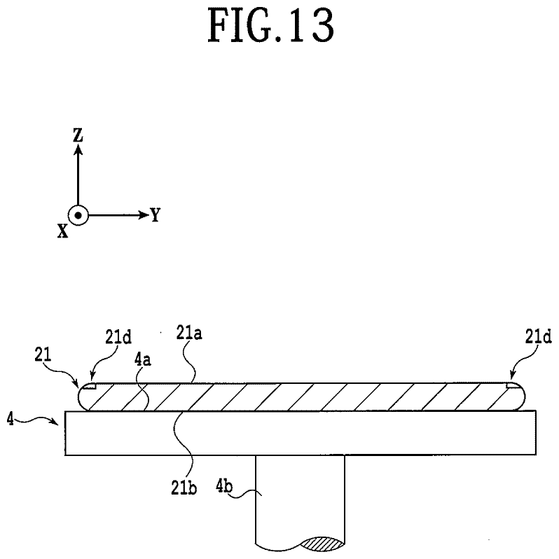

A second modification of the first embodiment will be described below with reference to FIG. 13. According to the second modification, as illustrated in FIG. 13, the recess 21d is expanded radially outwardly of the support plate 21 to form an annular step whose outer circumferential portion is open radially outwardly in the outer circumferential region 23b of the support plate 21 on the face 21a thereof.

FIG. 13 illustrates the recess 21d in the support plate 21 according to the second modification of the first embodiment. For example, the expanded recess 21d may be formed by cutting the support plate 21 with an edge-trimming cutting blade, not depicted, having a relatively large cutting edge thickness ranging from 2 mm to 4 mm, for example. Alternatively, the recess 21d that provides the annular step may be formed by adjusting the position along the Y-axis of the cutting unit 6 with respect to the holding surface 4a upon the first revolution of the chuck table 4 and the second or subsequent revolution thereof.

### Second Embodiment

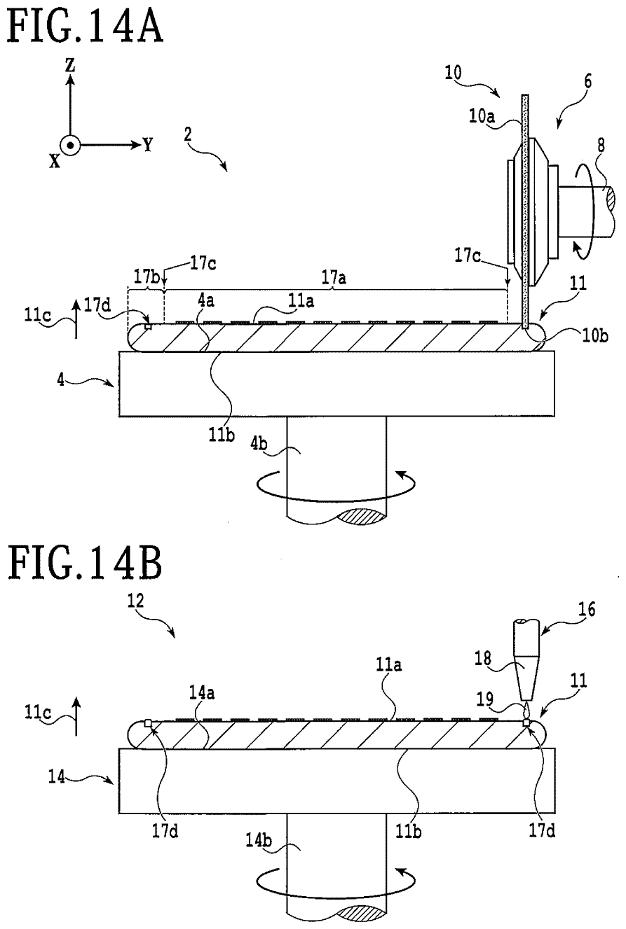

A second embodiment of the present invention will be described below with reference to FIGS. 14A and 14B. According to the second embodiment, a recess 17d extending circumferentially along the device wafer 11 is formed in the outer circumferential edge portion 17b of the face side 11a of the device wafer 11, instead of the support plate 21.

FIG. 14A illustrates recess forming step S10 according to the second embodiment in side elevation, partly in cross section. FIG. 14B illustrates resin supplying step S20 according to the second embodiment in side elevation, partly in cross section. In subsequent affixing step S30, the support plate 21 is lowered toward the device wafer 11. However, as with the first embodiment, the device wafer 11 may be lowered toward the support plate 21.

The recess 17d has a depth ranging from 0.04 mm to 0.09 mm from the face side 11a of the outer circumferential edge portion 17b, for example, and a width ranging from 1.0 mm to 3.0 mm, for example.

### Third Embodiment

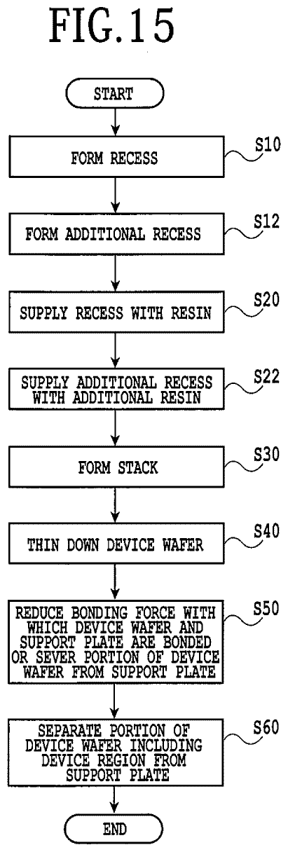

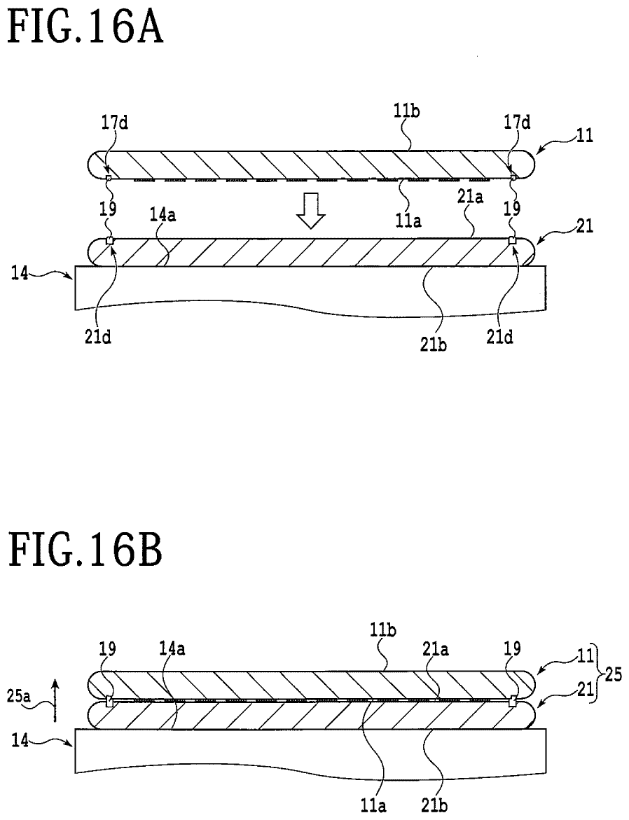

A third embodiment of the present invention will be described below with reference to FIGS. 15, 16A, and 16B. According to the third embodiment, the recess 17d is formed in the face side 11a of the device wafer 11, and the recess 21d is formed in the face 21a of the support plate 21.

FIG. 15 is a flowchart of a processing method according to the third embodiment. As illustrated in FIG. 15, before resin supplying step S20 and affixing step S30, recess forming step S10 is followed by step S12 of forming an additional recess (additional recess forming step).

In recess forming step S10, the annular recess 21d is formed in the face 21a. In additional recess forming step S12, the recess 17d is formed in the face side 11a. However, the recess 17d may be formed in the face side 11a in recess forming step S10, and the recess 21d may be formed in the face 21a in additional recess forming step S12.

In other words, in the face 21a of the support plate 21 and the face side 11a of the device wafer 11, the additional recess may be formed circumferentially in the outer circumferential edge portion 17b or the outer circumferential region 23b where no recess has been formed in recess forming step S10.

According to the third embodiment, the width of the recess 21d formed in the face 21a of the support plate 21 is larger than the width of the recess 17d formed in the face side 11a of the device wafer 11 (see FIGS. 16A and 16B).

For example, a cutting edge 10a having a relatively large thickness is used to form the recess 21d in the face 21a, and a cutting edge 10a having a relatively small thickness is used to form the recess 17d in the face side 11a. Alternatively, the recess 21d may be formed by moving the cutting edge 10a having the relatively small thickness in a plurality of repetitive cycles circumferentially along the support plate 21.

In a case where the support plate 21 and the device wafer 11 are positioned such that the face 21a and the face side 11a have their centers aligned with each other, the recess 21d and the recess 17d are formed in superposed positions circumferentially fully along the stack 25 in the thicknesswise direction 25a of the stack 25 (see FIG. 16B).

However, the present invention is not limited to the above details. In a case where the support plate 21 and the device wafer 11 are positioned such that the face 21a and the face side 11a have their centers aligned with each other, unless the recess 21d overlaps the device region 17a, the recess 21d and the recess 17d may partially overlap each other or may not fully overlap each other.

After recess forming step S10 and additional recess forming step S12 but before affixing step S30, resin supplying step S20 is carried out to supply a recess, i.e., one of the recess 17d and the recess 21d, with the liquid resin 19, and step S22 of supplying an additional recess, i.e., the other of the recess 17d and the recess 21d, with the liquid resin 19 (additional resin supplying step) is carried out.

The resin used in additional resin supplying step S22 may not contain completely identical components to those of the resin 19. FIG. 16A illustrates affixing step S30 according to the third embodiment in side elevation, partly in cross section, and FIG. 16B illustrates the stack 25 formed in affixing step S30 according to the third embodiment.

After affixing step S30, the same steps as those according to the first embodiment or the first modification thereof are carried out. Therefore, those steps are omitted from description. The second modification of the first embodiment may be applied to the third embodiment.

### Fourth Embodiment

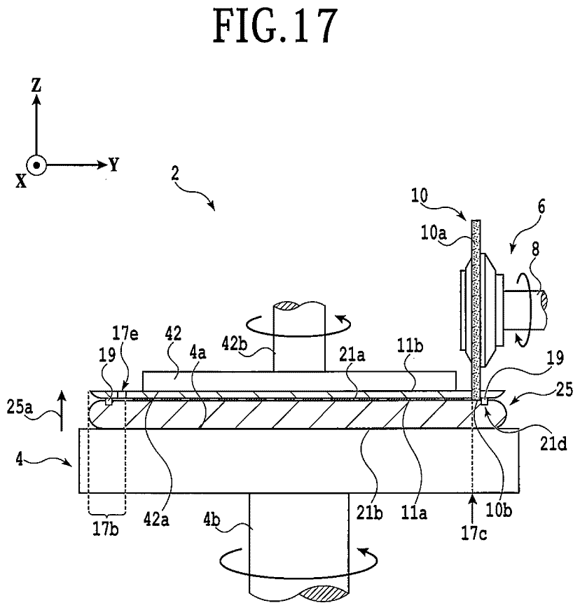

A fourth embodiment of the present invention will be described below with reference to FIG. 17. According to the fourth embodiment, in separation preparing step S50, the resin removing step of cutting the cured resin 19 is replaced with a step of forming an annular groove 17e (see FIG. 17) extending from the face side 11a to the reverse side 11b in the outer circumferential edge portion 17b of the device wafer 11, thereby separating the portion of the device wafer 11 including the device region 17a from the support plate 21 (annular groove forming step).

FIG. 17 illustrates the annular groove forming step in separation preparing step S50 according to the fourth embodiment in side elevation, partly in cross section. In the annular groove forming step illustrated in FIG. 17, the face 21b of the support plate 21 is held under suction on the chuck table 4, and the central portion of the reverse side 11b of the device wafer 11 is held under suction on the holding plate 42.

Then, the spindle 8 is rotated about its longitudinal central axis at a predetermined rotational speed, and the cutting unit 6 is lowered from above the device wafer 11, positioning the lower end 10b of the cutting edge 10a at a position deeper than the face side 11a of the device wafer 11 along the Z-axis, i.e., to make a chopper cut.

At this time, the lower end 10b of the cutting edge 10a may be positioned between the face side 11a and the face 21a to minimize wear on the cutting edge 10a as it does not cut the support plate 21. However, the lower end 10b of the cutting edge 10a may be positioned on the face 21a or may cut into a position in the support plate 21 that is deeper than the face 21a.

The lower end 10b of the cutting edge 10a that is positioned on the face 21a or in the position deeper than the face 21a is more reliably effective to avoid the situation in which the device wafer 11 and the support plate 21 would not be separated from each other because the annular groove 17e would not extend through the device wafer 11, leaving an uncut region in the device wafer 11.

Instead of making the chopper cut, the chuck table 4 may be moved along the X-axis while the lower end 10b of the rotating cutting edge 10a is fixed in position along the Z-axis, causing the cutting edge 10a to cut to a desired position in the roll-off region 23f, after which the chuck table 4 may start rotating about its vertical central axis.

In the annular groove forming step, with the cutting edge 10a thus cutting into the outer circumferential edge portion 17b of the device wafer 11, the chuck table 4 and the holding plate 42 are turned through the same angle per unit time. In this manner, the annular groove 17e is formed in the device wafer 11 radially outwardly of the device region 17a of the device wafer 11 and radially inwardly of an annular region thereof that is aligned with the recess 21d of the support plate 21, as viewed in plan with respect to the stack 25.

The annular groove 17e makes it possible to separate a disk-shaped region of the device wafer 11, i.e., a portion of the device wafer 11, that includes the device region 17a from the support plate 21. According to the fourth embodiment, less severe material constraints are imposed on the adhesive and the support plate 21 than with the related art.

### Fifth Embodiment

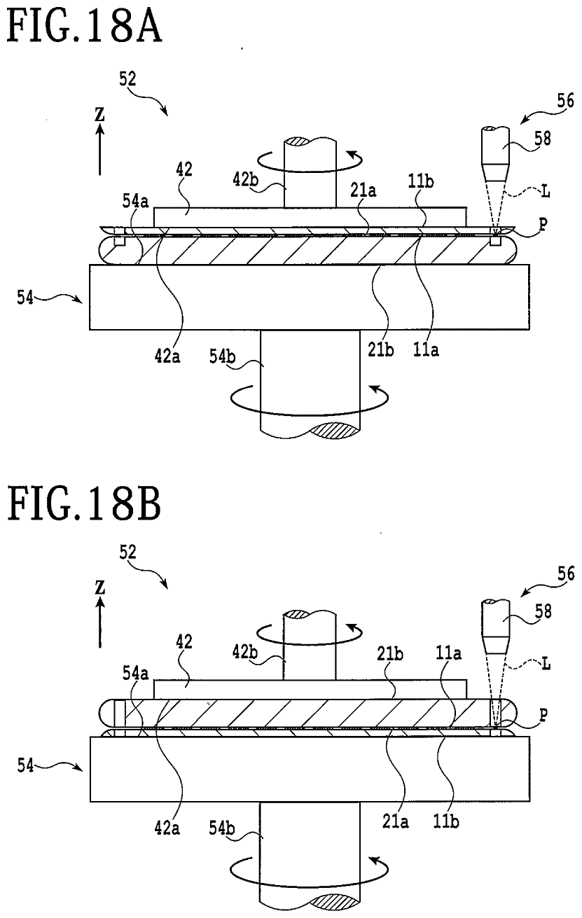

A fifth embodiment of the present invention will be described below with reference to FIG. 18A. According to the fifth embodiment, in separation preparing step S50, a laser processing apparatus 52 is used instead of the cutting apparatus 2 to perform the resin removing step.

The laser processing apparatus 52 will be described below with reference to FIG. 18A. As illustrated in FIG. 18A, the laser processing apparatus 52 has a chuck table 54 having an upper holding surface 54a. A rotational shaft 54b extending substantially parallel to the Z-axis has an upper end fixed centrally to a lower surface of the chuck table 54.

The chuck table 54 is structurally identical to the chuck table 4, and its redundant description will be omitted below. However, the chuck table 54 is movable along the X-axis and the Y-axis by a moving mechanism, not depicted, having ball screws.

The laser processing apparatus 52 also includes a laser beam applying unit 56 disposed above the chuck table 54. The laser beam applying unit 56 is movable along the Z-axis by a moving mechanism, not depicted, having a ball screw. The laser beam applying unit 56 includes a laser oscillator, not depicted, for emitting a pulsed laser beam.

The laser oscillator has a laser medium of Nd:YAG or Nd:YVO₄, for example. When the pulsed laser beam emitted from the laser oscillator passes through a nonlinear optical crystal in the pulsed laser beam applying unit 56, the laser beam is converted into a pulsed laser beam L having a wavelength of 355 nm, for example, absorbable by the device wafer 11, and the pulsed laser beam L is emitted from the laser beam applying unit 56.

The laser beam L travels through an optical system, not depicted, including a mirror to an irradiating head 58. The irradiating head 58 has a condensing lens, not depicted, that focuses the laser beam L onto a point positioned along the Z-axis.

FIG. 18A illustrates, in side elevation, partly in cross section, the manner in which the laser beam L is applied to the stack 25 in the resin removing step according to the fifth embodiment. In the resin removing step, the laser beam L from the irradiating head 58 is applied to the device wafer 11 through which the laser beam L travels from the reverse side 11b toward the face 21b of the support plate 21. The laser beam L that has traveled through the device wafer 11 is focused into a focused spot P that is positioned in the vicinity of the boundary between the face side 11a and the face 21a.

Then, the chuck table 54 and the holding plate 42 are turned through the same angle per unit time, removing the region of the resin 19 that contributes to the affixing of the device wafer 11 and the support plate 21 to each other, by way of ablation circumferentially along the device wafer 11.

The bonding force with which the device wafer 11 and the support plate 21 are bonded to each other along the thicknesswise direction 25a of the stack 25 is now reduced. As illustrated in FIG. 18B, the stack 25 may be turned upside down in its vertical orientation. An example of laser processing conditions is given below.
Wavelength of laser beam: 55 nm to 532 nm
Average output power: 0.5 W
Repetitive frequency: 40 kHz
Speed at which focused spot is fed: 1000 mm/s to 3000 mm/s

### Modification of Fifth Embodiment

A modification of the fifth embodiment will be described below with reference to FIG. 18B. FIG. 18B illustrates, in side elevation, partly in cross section, the manner in which the laser beam L is applied to the stack 25 in the resin removing step according to the modification of the fifth embodiment.

According to the modification of the fifth embodiment, the laser beam L is applied from the face 21b of the support plate 21 toward the reverse side 11b of the device wafer 11, and its focused spot P is positioned in the vicinity of the boundary between the face side 11a and the face 21a.

Then, the chuck table 54 and the holding plate 42 are turned through the same angle per unit time, removing the region of the resin 19 that contributes to the affixing of the device wafer 11 and the support plate 21 to each other by way of ablation circumferentially along the device wafer 11.

Although not illustrated, in separation preparing step S50, the laser processing apparatus 52 may be used to perform an annular groove forming step in the same manner as with the fourth embodiment (see FIG. 17). An example of laser processing conditions in the annular groove forming step is given below. The focused spot P may make one revolution or a plurality of revolutions around the rotational shaft 54b when the chuck table 54 and the holding plate 42 are turned through the same angle per unit time.
Wavelength of laser beam: 355 nm to 532 nm
Average output power: 6 W
Repetitive frequency: 10 kHz
Angle through which focused spot is turned per unit time around rotational shaft: 120°/s

### Sixth Embodiment

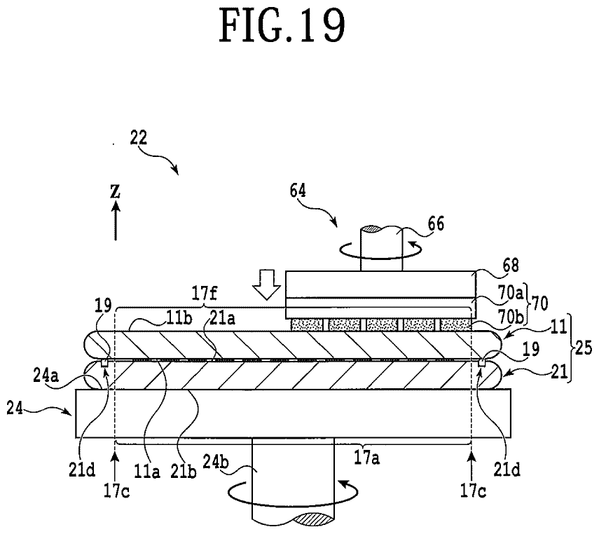

A sixth embodiment of the present invention will be described below with reference to FIGS. 19, 20, and 21. The sixth embodiment is the same as the first embodiment with regard to recess forming step S10 through affixing step S30. In thinning step S40, however, a process called “TAIKO” (registered trademark) is carried out. The process will hereinafter be referred to as the “TAIKO process.”

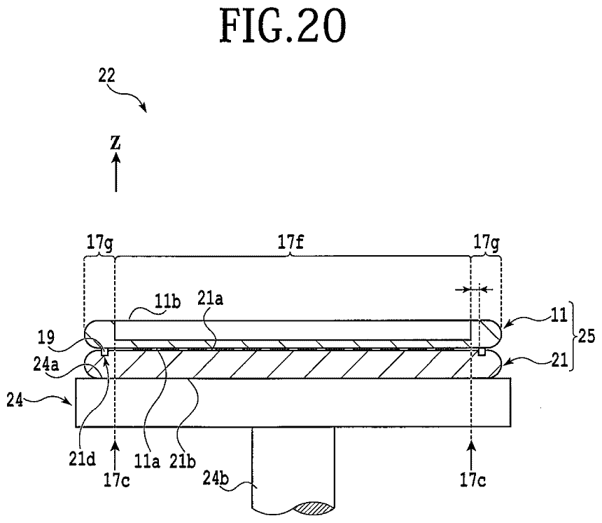

In thinning step S40 according to the sixth embodiment, not the entire reverse side 11b of the device wafer 1, but only a central portion 17f (see FIG. 19) of the reverse side 11b that is commensurate with the device region 17a of the face side 11a is thinned down (see FIG. 20).

As illustrated in FIG. 19, a grinding and polishing apparatus 22 has a grinding unit 64 for carrying out the TAIKO process, instead of the grinding unit 26b and the polishing unit 34. The grinding unit 64 has a cylindrical spindle 66 whose longitudinal central axis extends vertically along the Z-axis.

A rotary actuator, not depicted, such as an electric motor is coupled to a longitudinally central portion of the spindle 66. The spindle 66 has a lower end to which a disk-shaped wheel mount 68 is fixed. The wheel mount 68 has a lower surface on which an annular grinding wheel 70 is mounted.

The grinding wheel 70 has an annular base 70a of metal that has a lower surface on which there is mounted an annular array of grindstones 70b spaced at substantially equal angular intervals circumferentially along the base 70a. The grindstones 70b are arranged in an annular pattern having such a size that when the grinding wheel 70 is rotated about the central axis of the spindle 66, the outside diameter of an annular path followed by the grindstones 70b is substantially half of the diameter of the device region 17a.

The holding surface 24a of the chuck table 24 according to the sixth embodiment is of an upwardly protruding conical shape. However, a chuck table, not depicted, including an outer circumferential portion and a central portion protruding upwardly beyond an annular region between the outer circumferential portion and the central portion and having a dual-recess cross-sectional shape may be used.

FIG. 19 illustrates thinning step S40 according to the sixth embodiment, in side elevation, partly in cross section. In thinning step S40 according to the sixth embodiment, the face 21b of the support plate 21 is held under suction on the holding surface 24a such that the reverse side 11b of the device wafer 11 is exposed upwardly.

Then, after the chuck table 24 has been placed directly below the grinding unit 64, the rotational shaft 24b and the spindle 66 are rotated in respective predetermined directions, and the grinding unit 64 is lowered, i.e., grinding-fed, along the Z-axis at a predetermined speed.

During the grinding process, while an area where the grindstones 70b and the reverse side 11b are kept in contact with each other is supplied with grinding water such as pure water, the central portion 17f of the reverse side 11b is ground to thin down the device wafer 11. In this manner, a ring-shaped stiffener 17g is formed on an outer circumferential portion that is commensurate with the outer circumferential edge portion 17b (see FIG. 20). An example of grinding conditions in thinning step S40 is given below.
Rotational speed of grinding wheel: 4000 rpm
Rotational speed of chuck table: 300 rpm
Grinding feed speed: 0.8 μm/s
Flow rate of grinding water: 5.0 L/min

After the thickness of the central portion 17f of the device wafer 11 has reached a desired value, the grinding unit 64 is lifted. FIG. 20 illustrates, in side elevation, partly in cross section, the stack 25 that has gone thinning step S40 according to the sixth embodiment. In thinning step S40 according to the sixth embodiment, the coarse grinding process and the fine grinding process may be carried out. After the grinding process, the central portion 17f of the reverse side 11b may be polished.

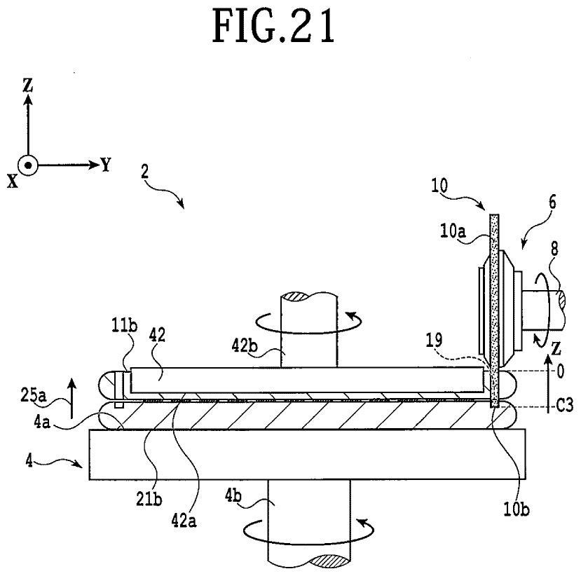

According to the sixth embodiment, thinning step S40 is followed by separation preparing step S50 in which the resin removing step is carried out using the cutting apparatus 2 described above. FIG. 21 illustrates, in side elevation, partly in cross section, the resin removing step in separation preparing step S50 according to the sixth embodiment.

In the resin removing step, the support plate 21 is held under suction on the chuck table 4, and the holding plate 42 is inserted into a disk-shaped space positioned radially inwardly of the ring-shaped stiffener 17g, after which the holding plate 42 holds the central portion 17f of the reverse side 11b under suction thereon.

While the lower end 10b of the cutting edge 10a of the cutting blade 10 is positioned at a third depth C3 extending from the reverse side 11b of the ring-shaped stiffener 17g, the region of the cured resin 19 that contributes to the affixing of the device wafer 11 and the support plate 21 to each other is removed circumferentially around the device wafer 11 by the cutting blade 10.

At this time, as described above, the timings of starting to rotate the chuck table 4 and the holding plate 42 are synchronized, and the chuck table 4 and the holding plate 42 are rotated at the same rotational speed. In separation preparing step S50 according to the sixth embodiment, the bonding force with which the device wafer 11 and the support plate 21 are bonded to each other along the thicknesswise direction 25a of the stack 25 is now reduced.

Instead of making the chopper cut, the chuck table 4 may be moved along the X-axis while the lower end 10b of the rotating cutting edge 10a is fixed in position along the Z-axis, causing the cutting edge 10a to cut to a desired position in the roll-off region 23f, after which the chuck table 4 may start rotating about its vertical central axis.

According to the sixth embodiment, as with the first modification (see FIG. 12) of the first embodiment, the chuck table 4 may hold the device wafer 11 under suction thereon, and the holding plate 42 may hold the support plate 21 under suction thereon. In this case, the diameter of the chuck table 4 is made smaller than the inside diameter of the ring-shaped stiffener 17g, and the chuck table 4 inserted into the disk-shaped space positioned radially inwardly of the ring-shaped stiffener 17g holds the central portion 17f of the reverse side 11b under suction thereon.

Moreover, as with the second modification (see FIG. 13) of the first embodiment, the recess 21d may be expanded radially outwardly of the support plate 21 to form an annular step whose outer circumferential portion is open radially outwardly in the outer circumferential region 23b of the support plate 21 on the face 21a thereof.

Furthermore, as with the second embodiment (see FIG. 14A), the recess 17d may be formed in the face side 11a of the device wafer 11, and as with the third embodiment (see FIG. 16A), the recess 17d may be formed in the face side 11a of the device wafer 11 and the recess 21d may be formed on the face 21a of the support plate 21.

### Modification of Support Plate

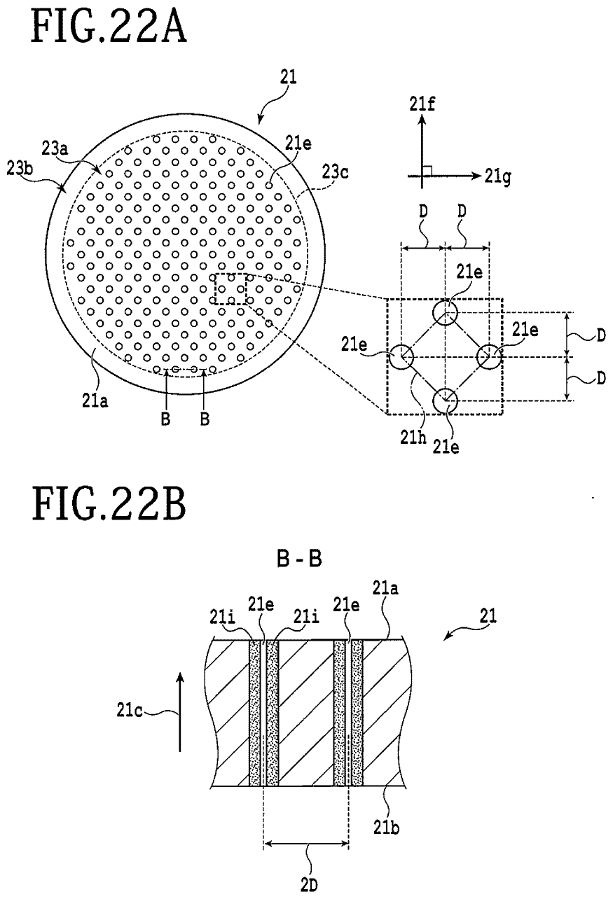

A modification of the support plate 21 will be described below with reference to FIGS. 22A and 22B. FIG. 22A illustrates, in plan, the support plate 21 according to the modification, and FIG. 22B is a cross-sectional view taken along line B-B of FIG. 22A.

The support plate 21 according to the modification includes a substrate of monocrystalline silicon and includes a plurality of substantially cylindrical pores 21e extending therethrough from the central region 23a of the face 21a along the thicknesswise direction 21c to the face 21b. Each of the pores 21e may be formed by way of laser ablation, for example.

The pores 21e have a diameter in a range from 1 μm to 20 μm, which is set to a predetermined value in a range from 10 μm to 20 μm, for example. However, the diameter of the pores 21e is not limited to the value mentioned. Each of the pores 21e may not necessarily be of a circular shape on the face 21a. Each of the pores 21e may be shaped as a right prism having a polygonal bottom surface or may be shaped otherwise.

The pores 21e are arranged in a regular pattern on the face 21a. As illustrated at an enlarged scale in a right inset in FIG. 22A, two closest pores 21e in a first direction 21f on the face 21a are spaced from each other by (predetermined distance D)×2, and two closest pores 21e in a second direction 21g, which is perpendicular to the first direction 21f, on the face 21a are also from each other by (predetermined distance D)×2. For example, the predetermined distance D represents 5.0 mm.

Stated otherwise, square shapes 21h whose each side has a size of (predetermined distance D)×(√2) are closely packed in the central region 23a of the face 21a, with pores 21e positioned at the respective vertexes of each square shape. In other words, the positions of the pores 21e thus correspond to the grid points of unit grids that are two-dimensionally packed in the central region 23a. The pores 21e are not limited to the pitch and layout illustrated in FIG. 22A.

As illustrated in FIG. 22B, a modified region 21i where the crystal property of monocrystalline silicon has been changed is formed around each of the pores 21e so as to extend from the face 21a to the face 21b in surrounding relation to the outside of the pore 21e.

The modified region 21i refers to a region where the crystal structure and density of part of the support plate 21 have been changed by receiving the energy from a laser beam. In FIG. 22B, the modified regions 21i are depicted as stippled, distinguishing themselves from regions depicted as hatched, i.e., regions where the crystal structure and density have not been changed.

Each of the modified regions 21i includes an amorphous region or a polycrystalline region. Each of the modified regions 21i has an inside diameter commensurate with the outside diameter of the pore 21e surrounded thereby. The outside diameter of each of the modified regions 21i represents 20 μm or less, for example.

For fabricating the support plate 21 according to the modification, a pulsed layer beam is applied to the support plate 21 to perform ablation thereon, for example, forming processed regions including pores 21e and modified regions 21i in the support plate 21. An example of processing conditions is given below.
Wavelength of laser beam: 1064 nm
Pulse energy: 50 μJ
Repetitive frequency of pulses: 1 kHz
Processing feed speed: 20 mm/s

The diameter, pitch, and layout of the pores 21e may appropriately be varied by changing the processing conditions. In addition to ablation, etching may further be applied to the support plate 21 with an alkaline etching solution, partially removing the modified regions 21i to increase the diameter of the pores 21e. The diameter of the pores 21e can be increased by adjusting the amount of the removed portion of the modified regions 21i.

In affixing step S30, when the face 21a of the support plate 21 that has the pores 21e and the face side 11a of the device wafer 11 are affixed to each other, gas that is positioned between the face 21a and the face side 11a can be discharged through the pores 21e.

Therefore, when the device wafer 11 is thinned down in thinning step S40, variations of the thickness of the device wafer 11 can be reduced and the thickness of the device wafer 11 can be uniformized with higher accuracy than if gas remained as gas bubbles between the face 21a and the face side 11a.

The support plate 21 with the pores 21e defined therein is not limited to the substrate of monocrystalline silicon but may be made of a material such as ceramic, glass, resin, or metal, for example, other than monocrystalline silicon.

The structural and methodical details of the embodiments described above may be changed or modified without departing from the scope of the invention. According to the above embodiments, the recess 17d in the device wafer 11 and the recess 21d in the support plate 21 includes single continuous annular slots or steps.

However, the recess 17d may be a plurality of discrete, i.e., unconnected and independent, slots disposed circumferentially along the face side 11a. Similarly, the recess 21d may also be a plurality of discrete slots or steps disposed circumferentially along the face 21a.

In a case where the resin 19 includes a thermosetting resin, the stack 25 may be heated to reduce the bonding force with which the device wafer 11 and the support plate 21 are bonded to each other by the resin 19 in separation preparing step S50, rather than being cut by the cutting blade 10 and ablated by the laser beam L.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing method of processing a device wafer having on a face side thereof a device region where devices have been formed and an excess outer circumferential region surrounding the device region, the method comprising:
forming a recess circumferentially along a support plate including a face having a size equal to or larger than a diameter of the device region and supporting the device wafer, in an outer circumferential region of the face that is positioned outwardly of a central region thereof that is commensurate with the device region, or circumferentially along the device wafer in the excess outer circumferential region of the face side of the device wafer;
supplying the recess with resin;
affixing the face of the support plate and the face side of the device wafer to each other with use of at least the resin, thereby forming a stack;
thinning down the device wafer by grinding or polishing or by grinding and polishing a reverse side of the device wafer that is positioned opposite the face side of the device wafer in a thicknesswise direction thereof;
removing a region of the resin that contributes to the affixing of the device wafer and the support plate to each other circumferentially along the device wafer, thereby to reduce a bonding force with which the device wafer and the support plate are bonded to each other in a thicknesswise direction of the stack, or forming an annular slot in the device wafer that extends from the face side to the reverse side thereof outwardly of the device region and inwardly of an annular region aligned with the recess, thereby to sever a portion of the device wafer that includes the device region from the support plate; and
separating the portion of the device wafer that includes the device region from the support plate.

2. The processing method according to claim 1, further comprising:
before the stack is formed, forming an additional recess circumferentially in the excess outer circumferential region or the outer circumferential region, which is free of the recess, of the face of the support plate and the face side of the device wafer; and
before the stack is formed, supplying the additional recess with an additional resin.

3. The processing method according to claim 1, wherein,
in supplying the recess with the resin, while a lower end of a cutting blade is positioned at a first depth from the reverse side of the device wafer or at a second depth from another face of the support plate that is positioned opposite the face of the support plate in a thicknesswise direction thereof, the region of the resin that contributes to the affixing of the device wafer and the support plate to each other is removed by the cutting blade circumferentially along the device wafer, thereby reducing the bonding force with which the device wafer and the support plate are bonded to each other in the thicknesswise direction of the stack.

4. The processing method according to claim 1, wherein,
in supplying the recess with the resin, a pulsed layer beam having a wavelength absorbable by the device wafer is applied from the reverse side of the device wafer to another face of the support plate that is positioned opposite the face of the support plate in a thicknesswise direction thereof or from the other face of the support plate to the reverse side of the device wafer, thereby to remove the region of the resin that contributes to the affixing of the device wafer and the support plate to each other circumferentially along the device wafer, thereby reducing the bonding force with which the device wafer and the support plate are bonded to each other in the thicknesswise direction of the stack.

5. The processing method according to claim 1, wherein,
in thinning down the device wafer, a central portion of the reverse side of the device wafer that is commensurate with the device region is thinned down to form a ring-shaped stiffener on an outer circumferential portion thereof that is commensurate with the excess outer circumferential region, and,
in reducing the bonding force with which the device wafer and the support plate are bonded to each other or in severing the portion of the device wafer from the support plate, the region of the resin that contributes to the affixing of the device wafer and the support plate to each other is removed circumferentially along the device wafer to reduce the bonding force with which the device wafer and the support plate are bonded to each other in the thicknesswise direction of the stack.

6. The processing method according to claim 1, wherein,
while the support plate is held on a holding table and the device wafer is held on a holding plate different from the holding table, the bonding force with which the device wafer and the support plate are bonded to each other is reduced or the portion of the device wafer is severed from the support plate.

7. The processing method according to claim 1, wherein
the support plate includes a plurality of pores extending therethrough from the central region of the face thereof along a thicknesswise direction of the support plate to another face of the support plate that is positioned opposite the face thereof, and,
in forming the stack, the face of the support plate and the face side of the device wafer are affixed to each other.
